(19) United States
(12) Patent Application Publication
(10) Pub. No.: US 2012/0199960 A1
(43) Pub. Date: Aug. 9, 2012

(54) WIRE BONDING FOR INTERCONNECTION BETWEEN INTERPOSER AND FLIP CHIP DIE

(75) Inventors: GLENN ENRICK CALDERON COSUE, BAGUIO CITY (PH); EDGARDO RULLODA HORTALEZA, BAGUIO CITY (PH); GERARDO CALDERON ANGELES, BAGUIO CITY (PH); TIMER DEREQUITO PORRAS, BAGUIO CITY (PH)

(73) Assignee: TEXAS INSTRUMENTS INCORPORATED, Dallas, TX (US)

(21) Appl. No.: 13/022,146

(22) Filed: Feb. 7, 2011

(51) Int. Cl. H01L 23/498; H01L 21/28

(52) U.S. Cl. 257/668; 257/737; 438/125; 438/107; 257/E23.068; 257/E21.158

(57) ABSTRACT

An integrated circuit (IC) device includes an interposer having a dielectric substrate having a first side, a second side, and an inner aperture, wherein a plurality of electrically conductive traces are on the first side. An IC die includes a topside semiconductor surface having active circuitry and a bottomside surface, wherein the topside semiconductor surface includes a plurality of bond pads, and is attached over the inner aperture onto the interposer. First wirebond interconnects couple respective bond pads to respective electrically conductive traces. A workpiece includes a top workpiece surface including a plurality of contact pads thereon attached to the first side of the interposer. Second interconnects couple respective conductive traces to respective contact pads on the workpiece.

### FIELD

Disclosed embodiments relate to integrated circuit (IC) devices, and more particularly to IC devices that include interposers.

### BACKGROUND

Low cost, high performance, high yield and quality (reliability) are all goals for packaged IC devices. Conventional electrical connections between the IC die to a substrate/workpiece is thru wirebond or flip chip. Flip chip and multi-chip modules (MCMs) generally provide high performance, but due to the packaging process flow complexity are not low cost, and may be subject to yield and quality issues. Such assembly flows may also pose problems for applications that require fine pitch die connections. What is needed is a new interconnection methodology scalable to a wide variety of package types that provides a relatively simple packaging process flow that is low cost, provides high yield and quality, and is suitable for fine pitch die connections.

### SUMMARY

Disclosed embodiments describe connective arrangements for integrated circuit (IC) devices that provide both physical and electrical connection where a metal tape (e.g., copper tape, referred to herein as a metal trace or simply a “trace”) interposer provides the connections for an IC die flip chip bonded to the interposer and from the interposer to substrate/workpiece inputs/outputs (I/Os). Wirebonds (bond wires or stud bumps) can be used to provide interconnects to both the IC die and workpiece sides of the interposer. Cut-out region(s) in the interposer dielectric allow close metal trace approach to bond pads on IC die, which allows short lengths for the bonding interconnects. Overhang portions of the metal trace that extend over the edge of the interposer dielectric on one or both the IC die and workpiece sides can be part of interconnect(s).

The tape interposer can include both an inner aperture (cut-out) region and an outer aperture region. The inner aperture region can be used for IC die that have core bond pads for core connections, and can be in addition to periphery connections provided by the outer aperture region for conventional periphery bond pads. Disclosed embodiments can utilize a conventional wirebond machine to form bond wires or stud bumps to connect the IC die to the tape interposer, and then the tape interposer to the workpiece without the use of a complex bonding layout/sequence, such as conventional flip chip mounting of the IC die to the workpiece and multi-chip modules (MCMs), thus being low cost compared to the cost of such high performance package options. Moreover, due to the relative assembly process simplicity disclosed, disclosed embodiments solve yield and quality issues associated with the high packaging process flow complexity of the current high performance packages. Moreover, since the tape interposer can also provide fine pitch metal traces, disclosed embodiments provide a solution to fine pitch connections to the IC die.

### BRIEF DESCRIPTION OF THE DRAWINGS

FIG. 1A is a plan view depiction showing an IC die flip chip bonded over an inner aperture of an interposer, according to an example embodiment.

FIG. 1B is a cross sectional depiction of the IC die bonded to the interposer shown in FIG. 1A taken along the cut line 1B indicated.

FIG. 2 is a cross sectional depiction of an IC device comprising the IC die flip chip bonded to the interposer shown in FIGS. 1A and 1B, with the interposer bonded to a workpiece shown as laminate substrate including a ball grid array (BGA).

FIGS. 3A-I show a variety of example wirebond interconnects that electrically and physically couple a trace on an interposer to a bond pad on an IC die, according to example embodiments.

FIG. 4 is a flow chart that shows steps in an example method of assembling an IC device where the IC die is flip chip bonded to the interposer, and the interposer is bonded to a workpiece, according to example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

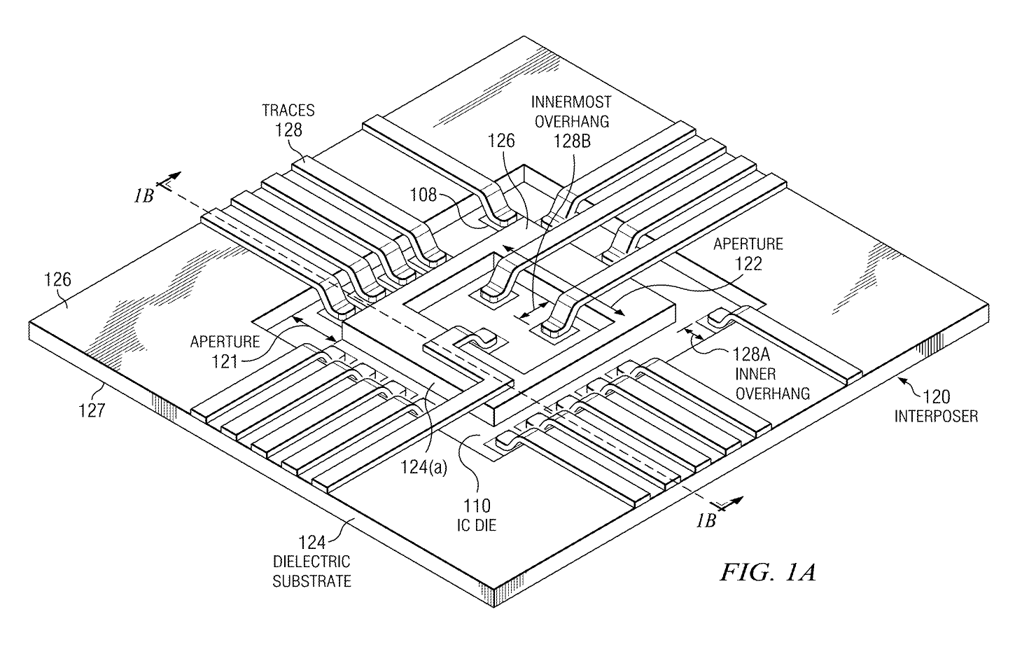

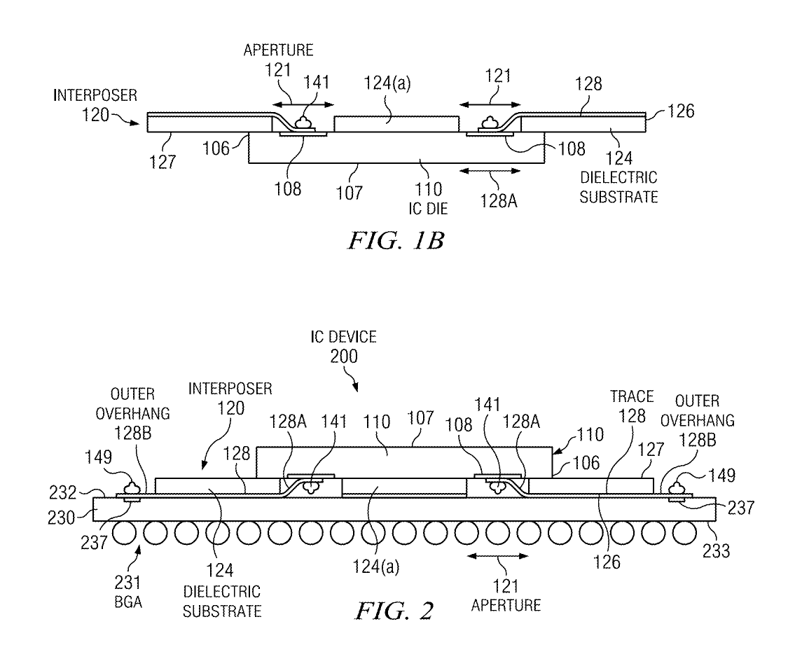

FIG. 1A is a plan view depiction and FIG. 1B a cross sectional depiction showing an IC die 110 bonded to a tape interposer 120 (interposer 120 shown on the top). The IC die 110 includes a topside semiconductor surface 106 having active circuitry (not shown) and a bottomside surface 107, where the topside semiconductor surface includes a plurality of bond pads 108. The active circuitry on the topside semiconductor surface of IC die is configured to provide an IC circuit function. The IC die 110 is bonded with its topside semiconductor surface 106 over an inner aperture 121 and optional second innermost aperture 122 of the dielectric substrate 124 of the interposer 120. Dielectric substrate 124 is shown in FIG. 1B including a center dielectric substrate portion 124(a) that is within aperture 121. Center dielectric substrate portion 124(a) provides additional mechanical support to help the interposer 120 supporting IC die and workpieces bonded thereto. Metal traces 128 can optionally extend over center dielectric substrate portion 124(a), or not be provided (e.g., be removed from the tape interposer).

Interposer 120 has a first side 126, a second side 127, and a plurality of electrically conductive traces 128 that are on the first side 126. The electrically conductive traces 128 can comprise copper or other metal or metal alloy. Interposer 120 can be regarded as a universal interposer since the disclosed metal trace interconnection methodology can be used to first create the IC die 110 to interposer 120 connection, and then later, the interposer 120 itself can be used to bond to a workpiece (tape, laminate, leadframe, ceramic, etc.) to create the routing to the package's input/outputs (IO's), such as solder ball, leads, etc, for a wide variety of workpieces including different packages (e.g., ball grid arrays (BGAs such as MICROSTAR BGA (single flexible polyimide layer substrate), Fine-Pitch Ball Grid Array (FBGA), Flip Chip Ball Grid Array (FCBGA), Plastic Ball Grid Array (PBGA), Quad Flat No-Lead (QFN), Quad Flat Package (QFP), and Wafer Level Chip Scale Package (WLCSP), etc.), and IC die having different IC die layouts (e.g., different die sizes, die shapes, different pad layouts, etc.).

Bond pads 108 of the IC die 110 on the topside semiconductor surface 106 are revealed through inner aperture 121 and optional second innermost aperture 122 of the interposer 120. As noted above, optional second innermost aperture 122 is for access to core bond pads 108 on the IC die, while inner aperture 121 is for access to periphery bond pads 108 on the IC die 110.

The dielectric substrate 124 for interposer 120 can include an organic dielectric polymer such as a polyimide or other organic dielectric tape materials. The interposer 120 can be fabricated by positioning an adhesive material layered between a polyimide or other flexible dielectric polymer single layer and a metal layer (e.g., copper foil, or aluminum foil). As known in the art, at a first step, a surface of the dielectric polymer layer is covered with a film adhesive that is protected by a removable, protective plastic sheet. After punching apertures/through-holes at desired locations to form inner aperture 121 and optional innermost aperture 122 based on the layout of the IC die to be bonded thereto, the protective sheet covering the adhesive layer is peeled off, thereby exposing the adhesive surface. A thin copper foil is laminated to the adhesive surface, thereby creating a dielectric polymer/adhesive/copper flexible tape interposer precursor having multiple holes in the polymer layer and no holes in the metal foil, such a 3-layer polyimide/adhesive/copper flexible tape substrate. Such tape interposer precursors can be provided by the 3M Company, St. Paul, Mn 55144. When the polymer tape substrate provides sufficient adhesion to the metal foil, the adhesive layer can be excluded.

The metal foil may then be patterned to form the plurality of traces 128 thru pholithographic techniques such as masking and etching, with the pattern based on the layout of the pads to be contacted. The trace overhang portions can be formed or defined by extending a length of the metal trace 128 to match the position of the pads to be contacted.

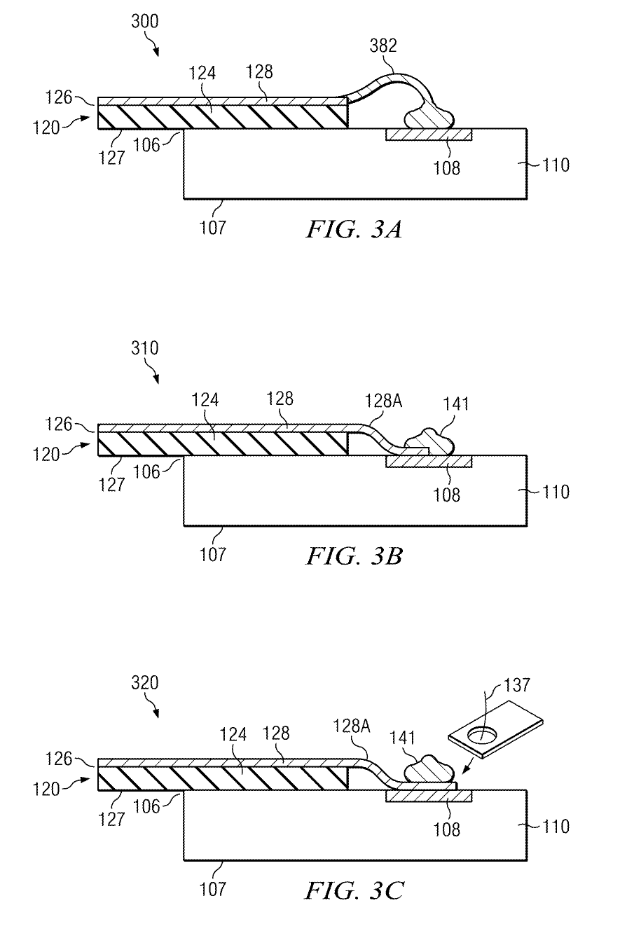

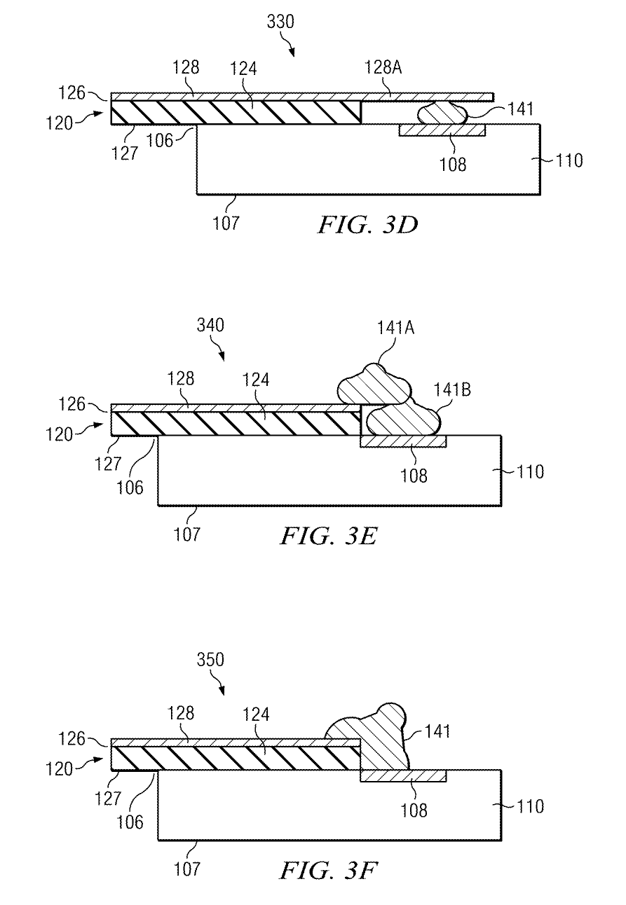

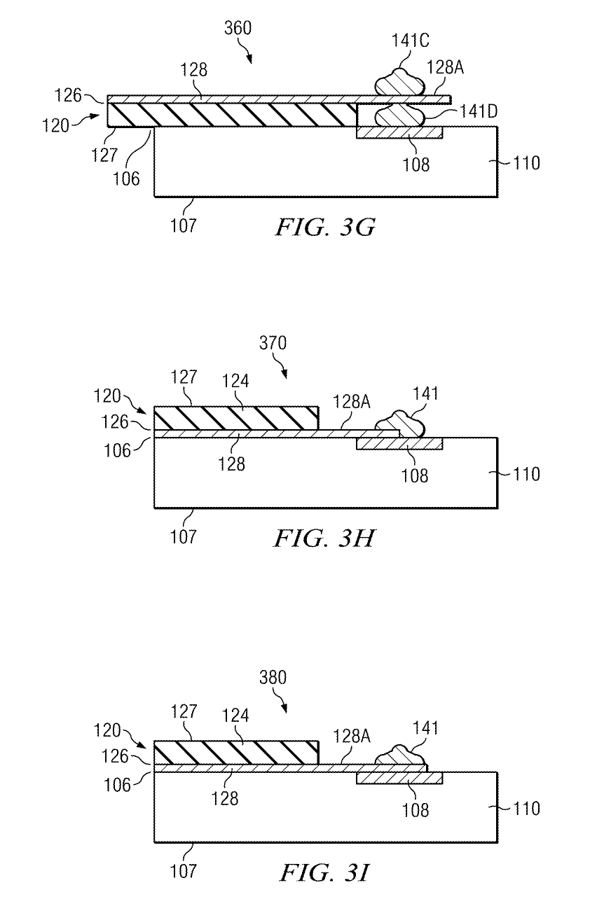

First wirebond interconnects 141 shown as stud bumps 141 in FIG. 1B couple respective bond pads 108 on IC 110 to respective metal traces 128 through contact to overhang portions 128A of traces 128 that extend over the outer edge of the inner aperture 121. More generally, first wirebond interconnects 141 or second wirebond interconnects 149 described below can comprise bond wires or one or more stud bumps, as described in detail below with respect to FIGS. 3A-I. Accordingly, a wire bonder or dedicated stud bumper, that is widely available and is well characterized, may be used to form the disclosed wirebonds. As known in the art, stud bumps, typically being gold stud bumps, are placed on the bond pads of the die through a modification of the “ball bonding” process used in conventional wire bonding. In ball bonding, the tip of the gold bond wire is melted to form a sphere. The wire bonding tool presses this sphere against the bond pad, applying mechanical force, heat, and ultrasonic energy to create a metallic connection. The wire bonding tool next extends the gold wire to the connection pad on the board, substrate, or lead frame, and makes a “stitch” bond to that pad, finishing by breaking off the bond wire to begin another cycle.

The IC die 110 can comprise as single IC die or a die stack. In one embodiment the IC can comprise a through-substrate via die, commonly referred to as a through-silicon via (TSV) die. In one particular embodiment the TSV die includes protruding TSV tips (e.g., copper tips) that extend out 5 to 15 microns from the bottomside surface 107 of the IC die 110 that enable bonding thereto. For example, in this particular embodiment, the TSV die can comprise a processor die having a memory die bonded to the protruding TSV tips of the processor die.

FIG. 2 is a cross sectional depiction of an IC device 200 comprising IC die 110 flip chip bonded to the interposer 120 shown in FIGS. 1A and 1B, with the first side 126 of the interposer 110 bonded to a contact pads 237 on a first side 232 of a workpiece 230 shown as laminate substrate 230 including a BGA 231 on its second side 233. More generally, workpiece 230 can be film-based (e.g. polyimide), a lead frame, organic laminate, ceramic, or comprise other composite materials.

Second interconnects 149 shown as stud bumps 149 couple outer overhang portions 128B of respective traces 128 to respective contact pads 237 on the first side 232 of the workpiece 230. Although second interconnects 149 are shown as stud bumps 149, the second interconnect 149 may also comprise bond wires, TAB-like bonding, electroplating, solder dispensing or mechanical riveting.

FIGS. 3A-I show a variety of wirebond interconnect embodiments that electrically and physically couple a trace 128 on an interposer 120 to a bond pad 108 on an IC die 110, according to example embodiments. Although FIGS. 3A-I are described herein for coupling an interposer to an IC die, those having ordinary skill in the art will recognize the coupling disclosed in FIGS. 3A-I can be also used for coupling an interposer to a workpiece, such as to a printed circuit board (PCB).

In arrangement 300 shown in FIG. 3A a tape interposer 120 is connected by a wire bond 382 that has a short wire length (e.g., less than 500 microns) and a low loop height (e.g., less than 75 microns) which is enabled by the proximity of the edge of the aperture 121 in dielectric substrate 124 to the bond pad 108, such as about 40 to 60 microns apart, or less. In arrangement 310 shown in FIG. 3B a trace 128 on an interposer 120 includes an overhang portion 128A that is connected through a stud bump 141 that provides mechanical welding to the top of the bond pad 108 with part of the area (e.g., diameter) of the stud bump 141 securing the overhang portion 128A of trace 128 to the bond pad 108.

In arrangement 320 shown in FIG. 3C a trace 128 on an interposer 120 includes an overhang portion 128A that is connected through a stud bump 141 to bond pad 108 with part of the diameter of the stud bump 141 holding the trace 128 by a distal end of the overhang portion 128A to the bond pad 108. The distal end of the overhang portion 128A of the trace 128 includes a hole 137 that the stud bump 141 fits over. In arrangement 330 shown in FIG. 3D an overhang portion 128A of trace 128 is connected through a stud bump 141 to the bond pad 108.

The distal end of the overhang portion 128A can also include a hole (analogous to hole 137 shown in FIG. 3C) that aligns with the stud bump 141. In arrangement 330 (and arrangements 340-360 described below) the stud bump 141 can be seen to be in a current conducting path provided by the interconnect.

FIG. 3E shows arrangement 340 where the trace 128 on the interposer 120 is connected to the bond pad 108 by providing two stud bumps 141A and 141B that overlap each other. In arrangement 340 the stud bumps 141A and 141B are in a current conducting path provided by the interconnect. Note that in arrangement 340 the stud bumps 141A/141B connect to the trace 128 on the interposer 120 directly, removing the need for an overhang portion 128A for trace 128 or a bond wire. A special capillary can be designed, such as by modifying the chamfer diameter, chamfer angle and tip diameter, so that the capillary can be used to form stud bumps 141A and 141B overlapping one another. FIG. 3F shows arrangement 350 where the trace 128 on the interposer 120 is connected to the bond pad 108 by a large stud bump 141.

FIG. 3G shows arrangement 360 where the overhang portion 128A of trace 128 on the interposer 120 is sandwich by two stud bumps 141C and 141D on top of each other. The overhang portion 128A can include an optional hole (analogous to hole 137 shown in FIG. 3C) that aligns with the stud bumps 141C and 141D. For the embodiments shown in FIGS. 3E-G, the stud bump material sticks up above the height of the metal traces 128 on the interposer 120. Additional of an encapsulating material can be used to improve planarity for such embodiments.

FIG. 3H shows arrangement 370 where the overhang portion 128A of trace 128 on interposer 120 is connected to the bond pad 108 with the stud bump 141 sitting partially on top of the distal end of the overhang portion 128A. FIG. 3I shows arrangement 380 where a distal end of the overhang portion 128A of trace 128 of interposer 120 is connected to the bond pad 108 with the stud bump 141 sitting completely (fully) on top of the distal end of the overhang portion 128A.

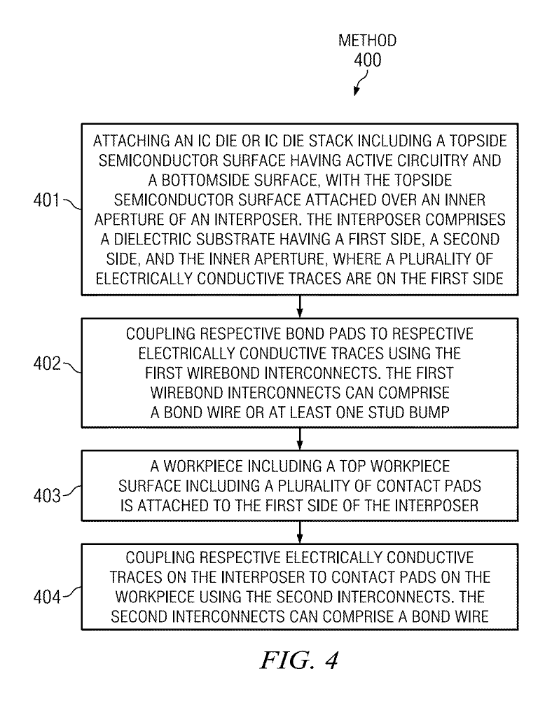

FIG. 4 is a flow chart that shows steps in an example method 400 of assembling an IC device where the IC die is flip chip bonded to an interposer, and the interposer is bonded to a workpiece, according to example embodiment. Step 401 comprises attaching an IC die or IC die stack including a topside semiconductor surface having active circuitry and a bottomside surface, wherein the topside semiconductor surface includes a plurality of bond pads, with the topside semiconductor surface attached over an inner aperture of an interposer. The interposer comprises a dielectric substrate having a first side, a second side, and an inner aperture, where a plurality of electrically conductive traces are on the first side. Step 402 comprises coupling respective bond pads to respective electrically conductive traces using first wirebond interconnects. The first wirebond interconnects can comprise a bond wire or at least one stud bump, such shown in FIGS. 3A-I described above. In step 403 a workpiece including a top workpiece surface including a plurality of contact pads is attached to the first side of the interposer. Step 404 comprises coupling respective electrically conductive traces on the interposer to contact pads on the workpiece using second interconnects. The second interconnect can comprise a bond wire, at least one stud bump, or TAB-like bonding, electroplating, solder dispensing or mechanical riveting.

Since disclosed embodiments can utilize a conventional wirebond machine to form bond wires and/or stud bumps to physically connect the IC die to the tape interposer, and then tape interposer to the workpiece without the use of a complex bonding layout/sequence, such as flip chip mounting of the IC die to the workpiece and multi-chip modules (MCMs), disclosed embodiments are low cost compared to the cost of such high performance package options. Moreover, due to relative simplicity of the disclosed assembly processes, disclosed embodiments solve yield and quality issues associated with the high packaging process flow complexity of the current high performance packages. Moreover, since the tape interposer can provide fine pitch metal traces, disclosed embodiments also provide a solution to fine pitch connections to closely spaced bond pads or other bonding features on the IC die. Moreover, disclosed embodiments are generally scalable to all packages types (e.g., various BGA packages, QFN, QFP, WLCSP, etc.).

The active circuitry formed on the IC die comprise circuit elements that may generally include transistors, diodes, capacitors, and resistors, as well as signal lines and other electrical conductors that interconnect the various circuit elements to provide an IC circuit function. As used herein “provide an IC circuit function” refers to circuit functions from ICs, that for example may include an application specific integrated circuit (ASIC), a digital signal processor, a radio frequency chip, a memory, a microcontroller and a system-on-a-chip or a combination thereof. Disclosed embodiments can be integrated into a variety of assembly process flows using a variety of workpieces to form a variety of devices and related products.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. An integrated circuit (IC) device, comprising:
an interposer comprising a dielectric substrate having a first side, a second side, and an inner aperture, wherein a plurality of electrically conductive traces are on said first side;
an IC die including a topside semiconductor surface having active circuitry and a bottomside surface, wherein said topside semiconductor surface includes a plurality of bond pads, and wherein said topside semiconductor surface is attached over said inner aperture onto said interposer;
first wirebond interconnects coupling respective ones of said plurality of bond pads to respective ones of said plurality of electrically conductive traces;
a workpiece including a top workpiece surface including a plurality of contact pads thereon attached to said first side of said interposer, and
second interconnects coupling respective ones of said plurality of electrically conductive traces to respective ones of said plurality of contact pads.

2. The IC device of claim 1, wherein said first wirebond interconnects comprise at least one stud bump.

3. The IC device of claim 2, wherein said stud bump is in a current conductive path provided by said first wirebond interconnects.

4. The IC device of claim 1, wherein said topside semiconductor surface is attached to said first side of said interposer.

5. The IC device of claim 1, wherein said topside semiconductor surface is attached to said second side of said interposer.

6. The IC device of claim 1, wherein at least some of said plurality of electrically conductive traces include an overhang portion that extends over said inner aperture.

7. The IC device of claim 1, wherein said inner aperture comprises a first inner aperture and a second innermost aperture, wherein said second innermost aperture is inside said first inner aperture and is separated by a portion of said dielectric substrate.

8. The IC device of claim 7, wherein some of said plurality of electrically conductive traces include an inner overhang portion that extends over said first inner aperture and some of said plurality of electrically conductive traces include an innermost overhang portion that extends over said first inner aperture and said second innermost aperture.

9. The IC device of claim 1, wherein at least some of said plurality of electrically conductive traces include an outer overhang portion that extends over an edge of said dielectric substrate opposite to said inner aperture, wherein said outer overhang portion is coupled by one of said second interconnects to one of said contact pads.

10. The IC device of claim 1, wherein said workpiece comprises a film-based substrate, an organic laminate, a leadframe, a ceramic substrate, an IC die, or an IC die stack.

11. The IC device of claim 1, wherein said interposer consists of a single dielectric layer.

12. A method of assembling an integrated circuit (IC) device, comprising:
attaching an IC die including a topside semiconductor surface having active circuitry and a bottomside surface, wherein said topside semiconductor surface includes a plurality of bond pads, with said topside semiconductor surface down over an inner aperture of an interposer, said interposer comprising a dielectric substrate having a first side, a second side, and said inner aperture, wherein a plurality of electrically conductive traces are on said first side;
coupling respective ones of said plurality of bond pads to respective ones of said plurality of electrically conductive traces using first wirebond interconnects;
attaching a workpiece including a top workpiece surface including a plurality of contact pads to said first side of said interposer, and
coupling respective ones of said plurality of electrically conductive traces to respective ones of said contact pads using second interconnects.

13. The method of claim 12, wherein said first wirebond interconnects comprise at least one stud bump.

14. The method of claim 13, wherein said stud bump is in a current conductive path provided by said first wirebond interconnects.

15. The method of claim 12, wherein at least some of said plurality of electrically conductive traces include an overhang portion that extends over said inner aperture.

16. The method of claim 12, wherein said inner aperture comprises a first inner aperture and a second innermost aperture, wherein said second innermost aperture is inside said first inner aperture and is separated by a portion of said dielectric substrate.

17. The method of claim 16, wherein some of said plurality of electrically conductive traces include an inner overhang portion that extends over said first inner aperture and some of said plurality of electrically conductive traces include an innermost overhang portion that extends over said first inner aperture and said second innermost aperture.

18. The method of claim 12, wherein at least some of said plurality of electrically conductive traces include an outer overhang portion that extends over an edge of said dielectric substrate opposite to said inner aperture, wherein said outer overhang portion is coupled by one of said second interconnects to one of said contact pads.

19. The method of claim 12, wherein said workpiece comprises a film-based substrate, an organic laminate, a leadframe, a ceramic substrate, an IC die or an IC die stack.

20. The method of claim 12, wherein said second interconnects comprise second wirebond interconnects, and wherein a wire bonder is used to form said first wirebond interconnects and said second wirebond interconnects.
